(19) United States
(12) Patent Application Publication
(10) Pub. No.: US 2016/0016192 A1
(43) Pub. Date: Jan. 21, 2016

(54) APPARATUS FOR MANUFACTURING WAVELENGTH CONVERSION PART AND METHOD OF MANUFACTURING WAVELENGTH CONVERSION PART USING THE SAME

(71) Applicant: Seoul Semiconductor Co., Ltd., Ansan-si (KR)

(72) Inventors: Byeong Ho Yang, Ansan-si (KR); Young Ju Lee, Ansan-si (KR); Kyoung Nam Kim, Ansan-si (KR)

(21) Appl. No.: 14/800,523

(22) Filed: Jul. 15, 2015

(30) Foreign Application Priority Data
Jul. 15, 2014 (KR) 10-2014-0089137
Jun. 25, 2015 (KR) 10-2015-0090649

(51) Int. Cl. B05C 5/00; B05C 9/10; B05C 11/10; H01L 33/50; H01L 33/00

(52) U.S. Cl. CPC B05C 5/001; H01L 33/502; H01L 33/005; B05C 11/1042; B05C 11/1015; B05C 9/10

(57) ABSTRACT

An apparatus for manufacturing a wavelength conversion part and a method for manufacturing a wavelength conversion part using the same are provided. According to an exemplary embodiment of the disclosed technology, an apparatus for manufacturing a wavelength conversion part of a light emitting apparatus is provided to include: a dispenser including a first storing part configured to store materials including a resin and phosphors; and a first temperature adjusting part connected to the dispenser, wherein the first temperature adjusting part includes a temperature sensor.

### CROSS-REFERENCE TO RELATED APPLICATIONS

This patent document claims priority and benefits of Korean Patent Application No. 10-2014-0089137, filed on Jul. 15, 2014, and Korean Patent Application No. 10-2015-0090649, filed on Jun. 25, 2015, which are hereby incorporated by reference for all purposes as if fully set forth herein.

### TECHNICAL FIELD

This patent document relates to an apparatus for manufacturing a wavelength conversion part and a method for manufacturing a wavelength conversion part using the same. For example, this patent document relates to an apparatus for manufacturing a wavelength conversion part capable of preventing phosphors from being deposited in a resin at the time of manufacturing the wavelength conversion part, and a method for manufacturing a wavelength conversion part using the same.

### BACKGROUND

Light emitting diodes (LEDs) have been used for a backlight light source of a display, a display element, an illumination apparatus, and the like. In general, a white light emitting diode implements white light by a combination of three primary colors of light. A method for implementing the white light from the light emitting diode generally includes a method for combining a blue LED chip and yellow phosphor, and a method for combining a UV LED chip and three phosphors of red, green, and blue. Typically, the phosphor has been used in a form in which the phosphor is mixed with an epoxy or a silicon support in a powder form and is coated on the LED chip.

### SUMMARY

This patent document provides an apparatus for manufacturing a wavelength conversion part capable of substantially and uniformly maintaining light emission characteristics of a plurality of light emitting apparatuses which are manufactured.

This patent document provides an apparatus for manufacturing a wavelength conversion part capable of substantially and uniformly maintaining light emission characteristics of a plurality of light emitting apparatuses which are mass-produced.

This patent document provides a method for manufacturing a wavelength conversion part capable of minimizing light emission deviation between the light emitting apparatuses manufactured by the apparatus for manufacturing the wavelength conversion part.

In one aspect, an apparatus for manufacturing a wavelength conversion part of a light emitting apparatus is provided to include: a dispenser including a first storing part configured to store materials including a resin and phosphors; and a first temperature adjusting part connected to the dispenser, wherein the first temperature adjusting part includes a temperature sensor.

In some implementations, the first temperature adjusting part may include a water cooler, and the water cooler may include: a circulation pipe at least partially surrounding the dispenser and providing a passage for water to flow, and a temperature adjusting apparatus connected to the circulation pipe to maintain a temperature of the water to be constant.

In some implementations, the first temperature adjusting part may include: a body; a thermoelement disposed in the body; an air circulation part disposed apart from the body and surrounding the dispenser; a first air passage connected to the body and introducing air into the body part; a second air passage connected to the body and moving the air between the body and the air circulation part; and a third air passage connected to the air circulation part and discharging the air from the air circulation part to the outside.

In some implementations, the body may include an air pump and an air circulation path circulating the air inside of the body, and the thermoelement adjusts the temperature of the air in the air circulation path to maintain a constant temperature.

In some implementations, the first temperature adjusting part may further include: a thermoelement; and a clamp in contact with the dispenser.

In some implementations, the temperature sensor may be in contact with the dispenser or the clamp.

In some implementations, the first temperature adjusting part may include an air compression cooler, and the air compression cooler may include: a compressor including refrigerant gas and compressing the refrigerant gas to provide a heated refrigerant gas; a cooler receiving the heated refrigerant gas from the compressor and cooling the received refrigerant gas to provide a liquefied refrigerant; an expanding valve receiving the liquefied refrigerant from the cooler and cooling the received liquefied refrigerant to provide the refrigerant gas; and a circulation pipe configured to at least partially surround the dispenser and providing a passage inside of the circulation pipe for the refrigerant gas provided from the expanding valve.

In some implementations, the first temperature adjusting part may maintain a temperature of the resin in the dispenser within a range of ±5° C. of a predetermined temperature.

In some implementations, the predetermined temperature may be in a range of −5° C. to 30° C.

In some implementations, the apparatus for manufacturing a wavelength conversion part may further include a first agitator mixing the phosphors in the resin.

In some implementations, the apparatus for manufacturing a wavelength conversion part may further include a first temperature maintainer maintaining a temperature of the resin supplied from the first agitator.

In some implementations, the first temperature maintainer may include: a second storing part storing the resin; and a second temperature adjusting part surrounding the second storing part, and the second temperature adjusting part may maintain a temperature of the resin in the second storing part within −5° C. to 30° C.

In some implementations, the apparatus for manufacturing a wavelength conversion part may further include a second temperature maintainer storing the resin supplied from the first temperature maintainer and maintaining a temperature of the resin.

In some implementations, the second temperature maintainer may include: at least one of third storing part storing the resin; and a third temperature adjusting part connected to the third storing part, and the third temperature adjusting part may maintain temperature of the resin in the third storing part within −5° C. to 30° C.

In another aspect, a method for manufacturing a wavelength conversion part is provided. The method includes: preparing a dispenser configured to hold a resin and phosphors; coating the resin to a light emitting apparatus from the dispenser, maintaining a temperature of the resin in the dispenser, and sensing a temperature of the heat exchange medium.

In some implementations, the temperature of the resin in the dispenser may be maintained within a range of ±5° C. of a predetermined temperature.

In some implementations, in the coating of the resin to the light emitting apparatus, the predetermined temperature may be in a range of −5° C. to 30° C.

In some implementations, the preparing of the dispenser includes mixing the resin with the phosphors.

In some implementations, the method for manufacturing a wavelength conversion part may further include: storing the mixed resin with the phosphors; and maintaining a temperature of the stored mixed resin within a range of 5° C. to 30° C.

In some implementations, the method for manufacturing a wavelength conversion part may further include: additionally performing a mixing process for the stored mixed resin.

### BRIEF DESCRIPTION OF THE DRAWINGS

FIG. 1 is a schematic view illustrating an exemplary apparatus for manufacturing a wavelength conversion part according to an embodiment of the disclosed technology;

FIG. 2A is a perspective view illustrating an example of the apparatus for manufacturing a wavelength conversion part according to an embodiment of the disclosed technology;

FIG. 2B is a perspective view illustrating another example of the apparatus for manufacturing a wavelength conversion part according to an embodiment of the disclosed technology;

FIG. 3 is a perspective view illustrating another example of the apparatus for manufacturing a wavelength conversion part according to an embodiment of the disclosed technology;

FIG. 4 is a perspective view illustrating another example of the apparatus for manufacturing a wavelength conversion part according to an embodiment of the disclosed technology;

FIGS. 5A and 5B are photographs comparing and illustrating a deposition degree of phosphors according to another exemplary embodiment of the disclosed technology and the related art;

FIG. 6 is a block diagram illustrating a configuration of an exemplary apparatus for manufacturing a wavelength conversion part and a method for manufacturing a wavelength conversion part according to another embodiment of the disclosed technology;

FIG. 7 is a block diagram illustrating a configuration of an exemplary apparatus for manufacturing a wavelength conversion part and a method for manufacturing a wavelength conversion part according to another embodiment of the disclosed technology;

FIG. 8 is a cross-sectional view illustrating a configuration of an exemplary apparatus for manufacturing a wavelength conversion part according to another embodiment of the disclosed technology;

FIG. 9 is a block diagram illustrating a configuration of an apparatus for manufacturing a wavelength conversion part and a method for manufacturing a wavelength conversion part according to another embodiment of the disclosed technology;

FIG. 10 is a block diagram illustrating a configuration of an apparatus for manufacturing a wavelength conversion part and a method for manufacturing a wavelength conversion part according to another embodiment of the disclosed technology;

FIG. 11 is a cross-sectional view illustrating a configuration of an exemplary apparatus for manufacturing a wavelength conversion part according to another embodiment of the disclosed technology; and

FIG. 12 is a schematic view illustrating a method for manufacturing a wavelength conversion part according to another embodiment of the disclosed technology.

### DETAILED DESCRIPTION

In the art, in order to implement the white light emitting diode, the light emitting diode chip is packaged. In this case, a wavelength conversion part disposed on a path of light emitted from the light emitting diode chip is disposed. As the wavelength conversion part, the phosphor is mainly used. For example, a method for supporting the phosphor in the resin encapsulating the LED chip is also used, or a method for disposing a phosphor sheet, or the like on a light emission path of the LED chip is also used. Among these, the method which is most widely used is to coat the LED chip with the resin including the phosphors in the process of packaging the LED. In this case, the resin is coated on the LED chip using a dispenser such as a syringe.

However, according to the method for coating the phosphor resin in the related art as described above, the phosphors in the syringe are deposited in a subject-support (resin) over a processing time, by which may cause light emission deviation of manufactured light emitting diode packages. That is, the phosphors may be deposited on a bottom of the resin over the processing time. As a result, a case in which more phosphors are included in the LED package which is manufactured later as compared to the LED package which is manufactured conveniently occurs. As a result, the light emission deviation between the LED packages manufactured in the same process is very increased, which has a bad influence on reliability, process yield, or the like of a product.

As well, as the processing time in which the phosphor resin is coated is increased, a curing of the resin may occur in the syringe. If the curing of the resin occurs, viscosity of the resin is changed, such that characteristics of the phosphor resin may be changed depending on a timing at which the LED package is manufactured. This change in the viscosity of the resin may occur according to a change in temperature. Since it is very difficult to expect the change in the viscosity of the resin, it is difficult to expect characteristics of the phosphor resin of the manufactured LED package. As a result, it is difficult to uniformly maintain light emission characteristics of the manufactured LED package.

In addition, it is required to mass-produce the LED package, but it is impossible to receive resin capacity required for the mass-production only by inner capacity of the dispenser. Thus, a separate storing part is required, but since the deposition of the phosphors consistently also occurs in the storing part, deviation between light emission characteristics of the manufactured LED package may be increased.

Therefore, there is a need for an apparatus and a method for manufacturing a wavelength conversion part capable of substantially and uniformly maintaining light emission characteristics of the LED package and being used for mass-producing the LED package, regardless of the processing timing of coating the phosphor resin.

Hereinafter, exemplary embodiments of the disclosed technology will be described in detail with reference to the accompanying drawings. The exemplary embodiments of the disclosed technology to be described below are provided by way of example to facilitate the understanding of the disclosed technology. Therefore, the disclosed technology is not limited to the exemplary embodiments set forth herein but may be modified in many different forms. In the accompanying drawings, widths, lengths, thicknesses, or the like, of components may be exaggerated for convenience. In addition, the case in which it is represented that one component is “on an upper portion of” or “above” another component is intended to include not only the case in which each part is “directly on an upper portion of” or “directly above” another part but also the case in which the other component is between each component and another component. Like reference numerals denote like elements throughout the specification.

In exemplary embodiments to be described below, the disclosed technology will be described with reference to an apparatus for manufacturing a wavelength conversion part used in a light emitting apparatus. The light emitting apparatus may include, for example, a light emitting diode package or module including light emitting diodes, or the like. However, the disclosed technology is not limited thereto, and the apparatus for manufacturing the wavelength conversion part may be used even in the case in which the wavelength conversion part used in various kinds of different light emitting apparatuses is manufactured.

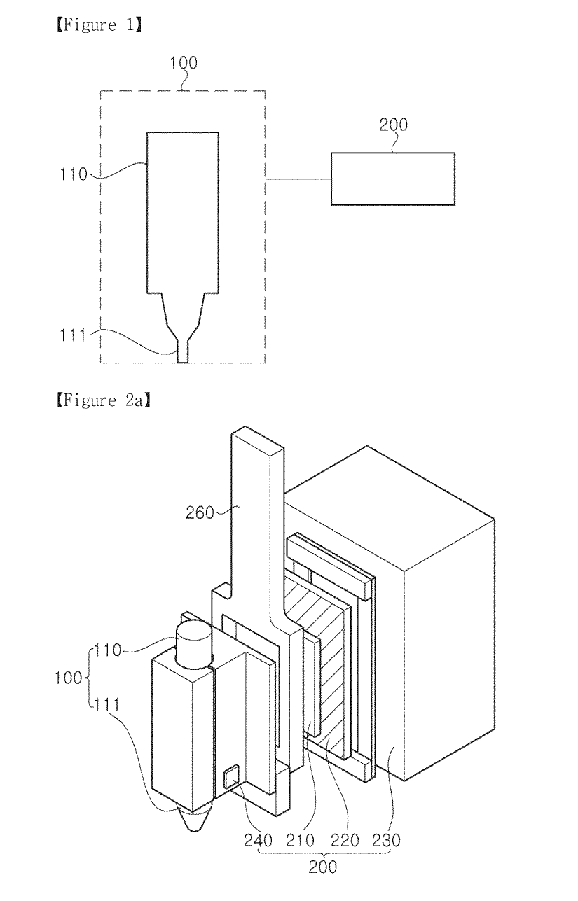

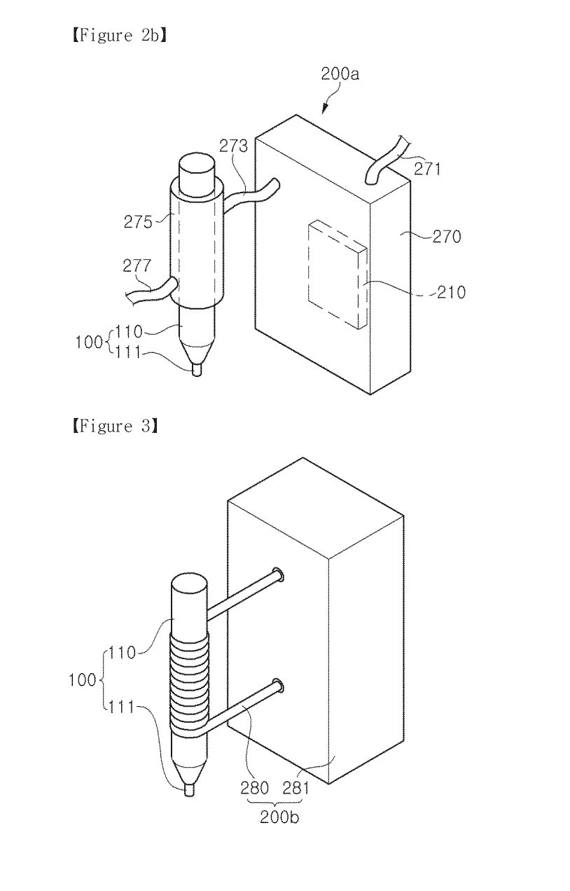

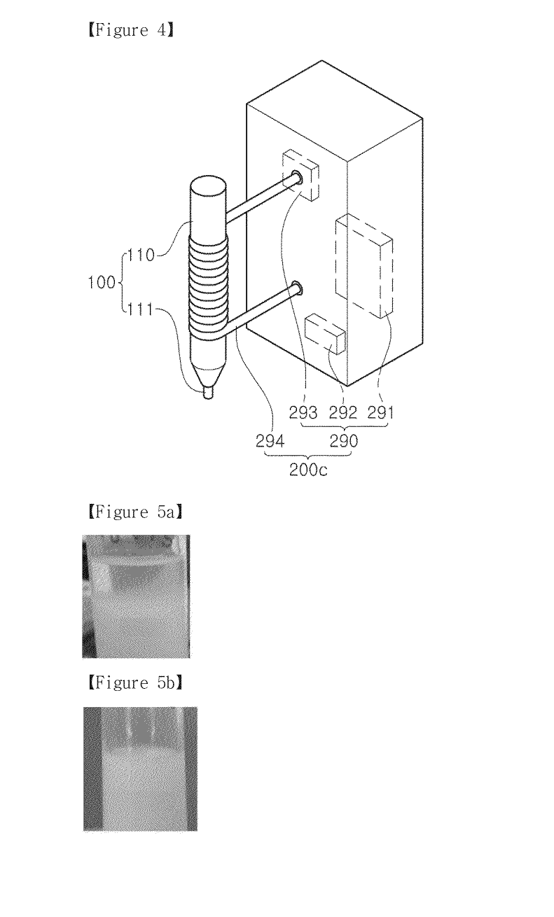

FIG. 1 is a schematic view illustrating an exemplary apparatus for manufacturing a wavelength conversion part according to an embodiment of the disclosed technology, FIG. 2A is a perspective view illustrating an example of the apparatus for manufacturing a wavelength conversion part according to an embodiment of the disclosed technology, FIG. 2B is a perspective view illustrating another example of the apparatus for manufacturing a wavelength conversion part according to another embodiment of the disclosed technology, and FIG. 3 is a perspective view illustrating another example of the apparatus for manufacturing a wavelength conversion part according to another embodiment of the disclosed technology. FIG. 4 is a perspective view illustrating another example of the apparatus for manufacturing a wavelength conversion part according to another embodiment of the disclosed technology.

Referring to FIG. 1, the apparatus for manufacturing a wavelength conversion part includes a dispenser 100 and a first temperature adjusting part 200.

The dispenser 100 may include a first storing part 110 in which a material manufactured by the wavelength conversion part, for example, a material such as a resin including phosphors is disposed, and a supplying part 111 through which the material is supplied to another component.

The resin in which the phosphors are uniformly mixed and supported may be disposed in the first storing part 110 of the dispenser 100. The phosphors and the resin may be prepared by being mixed and combined with each other. The supplying part 111 may serve as a supplying path through which the resin is discharged and applied to the light emitting apparatus.

The dispenser 100 may be or include various types of dispensers which are known to those skilled in the art, and may be or include, for example, a syringe type of dispenser including the first storing part 110 and the supplying part 111.

Meanwhile, the resin may include a polymer resin such as an epoxy resin or an acrylic resin, or a silicon resin, as a main material, and may serve as a matrix diffusing the phosphors. In some implementation, the resin may further include a curing agent. Thus, the resin in which the phosphors are supported may be cured after being supplied to the light emitting apparatus.

The first temperature adjusting part 200 may be connected to the dispenser 100 and may adjust temperature of the dispenser 100. For example, the first temperature adjusting part 200 may adjust inner temperature of the first storing part 110 of the dispenser 100. The first temperature adjusting part 200 may maintain inner temperature of the dispenser 100 at a temperature within a predetermined range. For example, the first temperature adjusting part 200 may maintain the inner temperature of the dispenser 100 within a range of ±5° C. of a predetermined temperature. In some implementations, the first temperature adjusting part 200 may maintain the inner temperature of the dispenser 100 within a range of ±3° C. of a predetermined temperature. Further, the first temperature adjusting part 200 may maintain the inner temperature of the dispenser 100 to be substantially constant.

In some implementations, the first temperature adjusting part 200 may adjust the inner temperature of the dispenser 100 within the range of −5° C. to −30° C. In some implementations, the first temperature adjusting part 200 may adjust the inner temperature of the dispenser 100 within the range of −5° C. to 25° C. In some implementations, the first temperature adjusting part 200 may adjust the inner temperature of the dispenser 100 within the range of −5° C. to 20° C. In the case in which the inner temperature of the dispenser 100 is set to a temperature out of the above-mentioned range, a variation rate of viscosity over time may be too high, or a curing reaction may occur too slowly. The above inner temperatures of the dispenser 100 have been provided as an example, and thus, the present invention is not limited thereto and other implementations are also possible.

Hereinafter, a curing mechanism of the resin including the main material and the curing agent will be described in detail. Further, an effect of the apparatus for manufacturing a wavelength conversion part according to the disclosed technology will be described.

The curing agent is acted as a cross linker to cure the main material, thereby curing the resin. In this case, the resin may also further include a curing retarder to adjust a curing time, or the like. In addition, the curing of the resin is a mechanism in which the viscosity of the resin is changed by heat as the curing proceeds. The curing process proceeds depending on temperature of the resin. For example, a degree of curing may be adjusted depending on temperature of the resin. Thus, the curing time and viscosity variation rate of the resin may be significantly changed depending on a process temperature. Further, in a process in which the resin is combined and mixed with the phosphors, the temperature of the resin may be changed depending on a mixing method and time. In this case, i.e., if the temperature of the resin becomes different while being prepared by mixing, such temperature change of the resin also affects the curing process. Thus, the curing time and viscosity variation rate of the resin may also be significantly changed.

In the related art, it is difficult to accurately predict the curing time and viscosity variation rate of the resin. Thus, the wavelength conversion part tends to have different characteristics depending on when the wavelength conversion part is manufactured. Thus, light emission characteristics of the manufactured light emitting apparatus are not constant, and deviation in characteristics between the light emitting apparatuses which are manufactured in the same process occurs.

However, according to implementations of the disclosed technology, the first temperature adjusting part 200 may adjust the inner temperature of the dispenser 100 to maintain the inner temperature of the dispenser 100 to be constant. In the case in which the inner temperature of the dispenser 100 is maintained to be constant, it is possible to prevent the viscosity variation rate from being different according to a process of manufacturing the wavelength conversion part. Further, it is also possible to substantially maintain the resin curing time to be constant. Therefore, the occurrence of the deviation in the light emission characteristics between the light emitting apparatuses which are manufactured in the same process is minimized, thereby making it possible to improve a process yield.

In addition, by adjusting the inner temperature of the dispenser 100 to be substantially constant within the range of −5° C. to 30° C., it is possible to minimize viscosity variation of the resin. Thus, it is possible to prevent the phosphors from being deposited on a lower portion of the resin. By preventing the phosphors from being deposited on the lower portion of the resin in the first storing part 110 during the process of manufacturing the wavelength conversion part, the occurrence of the deviation in the light emission characteristics between the light emitting apparatuses using the wavelength conversion part manufactured by using the apparatus for manufacturing a wavelength conversion part is minimized, thereby improving the process yield.

Various methods which are known to those skilled in the art may be used for the first temperature adjusting part 200. The first temperature adjusting part 200 may be operated by various temperature adjusting methods. The dispenser 100 may be in contact with a heat exchanging medium according to the respective temperature adjusting methods. In this case, temperature of the heat exchanging medium may be measured by a temperature sensor, and the temperature may be frequently adjusted according to the temperature of the heat exchanging medium measured by the temperature sensor. The heat exchanging medium may be or include a refrigerant such as air, water, or the like, and may be configured as a clamp, or the like. However, the heat exchanging medium is not necessarily limited thereto, and any heat exchanging medium may be used as long as it is capable of performing heat-exchange with the dispenser 100. Hereinafter, configurations of the first temperature adjusting part 200 according to the respective temperature adjusting methods will be described.

For example, the first temperature adjusting part 200 may include a thermoelement. The apparatus for manufacturing a wavelength conversion part including the thermoelement will be described in detail with reference to FIG. 2A. FIG. 2A illustrates an example of the first temperature adjusting part 200 including the thermoelement and the dispenser 100.

Referring to FIG. 2A, the apparatus for manufacturing a wavelength conversion part of FIG. 2A may include the dispenser 100 and the first temperature adjusting part 200 including a thermoelement 210. Further, the first temperature adjusting part 200 may further include a heat dissipating plate 220, a cooler 230, and a temperature sensor 240. In addition, the apparatus for manufacturing a wavelength conversion part may further include a body part 260.

As illustrated, the dispenser 100 may have a syringe shape. The dispenser 100 may include the first storing part 110 and the supplying part 111. Since the first storing part 110 and the supplying part 111 are similar to those described above, a detailed description thereof will be omitted. In addition, the dispenser 100 may be fixed or provided by various methods, and may be, for example, fixed by the clamp as illustrated.

The thermoelement 210 may include an element inducing heat to be absorbed or generated. The thermoelement 210 may be connected to the dispenser 100 to adjust the temperature of the dispenser 100, and may be further connected to the clamp fixing the dispenser 100, thereby allowing the heat exchange between the dispenser 100 and the thermoelement 210 to be performed through the clamp.

In addition, the first temperature adjusting part 200 may further include the heat dissipating plate 220 and the cooler 230 which are connected to the thermoelement 210. The heat dissipating plate 220 and the cooler 230 may serve to more effectively discharge heat generated from the thermoelement 210. A material of the heat dissipating plate 220 is not limited, and may include, for example, a metal having excellent heat conductivity.

Meanwhile, the body part 260 may be interposed between the dispenser 100 and the thermoelement 210, and the body part 260 may fix the dispenser 100 and the thermoelement 210 to each other. In some implementations, the body part 260 may be omitted.

Further, the first temperature adjusting part 200 may further include the temperature sensor 240. The temperature sensor 240 may serve to measure the temperature of the dispenser 100, for example, the inner temperature of the dispenser 100 to assist in adjusting a degree of absorption and generation of heat of the thermoelement 210. In this case, a controlling unit (not illustrated) obtaining data from the temperature sensor 240 to adjust the operation of the thermoelement may be further disposed.

The temperature sensor 240 may also be disposed to be in contact with the dispenser 100, or may also be disposed to be in contact with the clamp fixing the dispenser 100 as illustrated. Alternatively, the temperature sensor 240 may be in contact with the thermoelement 210. However, the disclosed technology is not limited thereto.

Although the exemplary embodiment of FIG. 2A has been provided to explain the adjusting of temperature, the disclosed technology is not limited to the exemplary embodiment of FIG. 2A, and the apparatus for manufacturing a wavelength conversion part according to the disclosed technology may adjust temperature in a different manner. For example, the first temperature adjusting part 200 may include an air-cooled type temperature adjusting part as illustrated in FIG. 2B, or may also include a water cooler as illustrated in FIG. 3.

An exemplary embodiment of FIG. 2B is different from the exemplary embodiment of FIG. 2A in the method of adjusting the temperature of the dispenser 100. Hereinafter, the description will be provided based on the difference, and a detailed description of the same configuration will be omitted.

Referring to FIG. 2B, the apparatus for manufacturing a wavelength conversion part 2A may include the dispenser 100 and a first temperature adjusting part 200a including the thermoelement 210. The first temperature adjusting part 200a may include a body 270, a thermoelement 210, first to third air passages 271, 273, and 277, and an air circulation part 275. Further, the first temperature adjusting part 200a may further include the temperature sensor.

The first air passage 271 and the second air passage 273 may be connected to the body 270, the first air passage 271 may provide a passage into which external air is introduced, and the second air passage 273 may provide a passage through which air is discharged from the body 270 to the outside. In this case, the second air passage 273 may be connected to the air circulation part 275, and the third air passage 277 may be connected to the air circulation part 275. In the air circulation part 275, the second air passage 273 may provide a passage into which the air is introduced, and the third air passage 277 may provide a passage through which the air is discharged to the outside.

Hereinafter, an operation principle of the first temperature adjusting part 200a will be described.

The external air may be introduced into the body 270 through the first air passage 271, and the introduced air may be circulated in the body 270. In this case, the air circulated in the body 270 is adjusted so as to maintain constant temperature by the thermoelement 210. The body 270 may include an apparatus capable of introducing the air through the first air passage 271 and circulating the air therein, and may include, for example, an air pump. In addition, the body 270 may further include an air circulation path capable of adjusting temperature of the circulated air therein, and the air circulation path may be connected to the thermoelement 210. In addition, the body 270 may further include various heat dissipating apparatuses to effectively discharge heat from the introduced air, and may further include, for example, a heat dissipating fin, a heat dissipating pad, or a heat dissipating fan, and the like.

The air is circulated in the body 270 and adjusted to have the constant temperature. Then, the air is moved to the air circulation part 275 through the second air passage 273. In this case, the air may be moved to the second air passage 273 by the air pump in the body 270, or the like. The air of which the temperature is adjusted by the second air passage 273 is circulated in the air circulation part 275. Thus, inner temperature of the first storing part 110 may be maintained to be substantially the same as that of the air circulation part 275. The air circulated in the air circulation part 275 may be discharged to the outside through the third air passage 277, and air of constant temperature may be consistently supplied to the air circulation part 275 through the second air passage 273. Therefore, even in the case in which the temperature of the air in the air circulation part 275 is increased by a heat exchange of air in the first storing part 110 and the air circulation part 275, the air of which the temperature is increased may be discharged through the third air passage 277 and the air of the constant temperature may be consistently supplied through the second air passage 273. Further, the first temperature adjusting part 200a may further include a temperature sensor (not illustrated). The temperature sensor may serve to measure the inner temperature of the dispenser 100 to assist in adjusting a degree of absorption and generation of heat of the thermoelement 210. In addition, unlike this, the temperature sensor may measure the temperature of the circulated air and assist in adjusting the temperature of the air so that the temperature of the air which is consistently circulated is maintained within a predetermined range.

FIG. 3 is a perspective view illustrating another example of the apparatus for manufacturing a wavelength conversion part according to an embodiment of the disclosed technology.

Referring to FIG. 3, the apparatus for manufacturing a wavelength conversion part of FIG. 3 may include the dispenser 100 and a first temperature adjusting part 200b including a circulation pipe 280 and a temperature adjusting apparatus 281.

A liquid may be circulated in the circulation pipe 280. For example, water may be circulated in the circulation pipe 280. The water may be pumped by the temperature adjusting apparatus 281 to be consistently circulated in the circulation pipe 280. In this case, the temperature adjusting apparatus 281 may include a refrigerant, or the like to allow the circulated water to be substantially maintained at a constant temperature.

A portion of the circulation pipe 280 may surround at least a portion of the dispenser 100. As illustrated, the circulation pipe 280 may surround the dispenser 100 in a spiral type, thereby making it possible to maintain the inner temperature of the dispenser 100 to be approximately the same as the temperature of the water in the circulation pipe 280. Therefore, if the temperature of the water in the circulation pipe 280 is maintained to be constant by the temperature adjusting apparatus 281, the temperature of the dispenser 100 may also be maintained to be constant. Further, the first temperature adjusting part 200b may further include a temperature sensor (not illustrated). The temperature sensor may serve to measure the inner temperature of the dispenser 100 to assist in adjusting a temperature of the resin. In some implementations, the temperature sensor may measure the temperature of the air being circulated and assist in adjusting the temperature of the water so that the temperature of the water which is consistently circulated is maintained within a predetermined range.

FIG. 3 and relevant descriptions have been provided as an example for the first temperature adjusting part 200b and the disclosed invention is not limited to the description of FIG. 3.

FIG. 4 is a perspective view illustrating another example of an apparatus for manufacturing a wavelength conversion part according to an embodiment of the disclosed technology.

Referring to FIG. 4, the apparatus for manufacturing a wavelength conversion part of FIG. 4 may include the dispenser 100, a temperature adjusting apparatus 290 including a compressor 291, a cooler 292, and an expanding valve 293, and a first temperature adjusting part 200c including a circulation pipe 294.

The compressor 291 serves to heat refrigerant gas by compressing the refrigerant gas. The refrigerant gas discharged from the compressor 291 is injected into the cooler 292. The cooler 292 converts the refrigerant gas into a liquefied state by cooling the refrigerant gas. In this case, a cooling method may use a heat exchange with the outside and a separate coolant may also be used. Regarding the cooling method, the disclosed technology is not limited thereto and other implementations are also possible. The refrigerant of the liquefied state discharged from the cooler 292 is again cooled while passing through the expanding valve 293, and is partially evaporated at the same time. The refrigerant discharged from the expanding valve 293 may be injected into the circulation pipe 294. The description of the circulation pipe 294 is similar to that described above with reference to FIG. 3. As a result, the inner temperature of the dispenser 100 may be maintained to be approximately the same as temperature of the refrigerant in the circulation pipe 294. The refrigerant of which the temperature is increased by receiving the heat from the dispenser 100 may be introduced into the first temperature adjusting part 200c and go through the same process, thereby being again used to adjust the inner temperature of the dispenser 100. Further, the first temperature adjusting part 200c may further include a temperature sensor (not illustrated). The temperature sensor may serve to measure the inner temperature of the dispenser 100 to assist in adjusting a temperature of the resin. In some implementations, unlike this, the temperature sensor may measure the temperature of the circulated refrigerant and assist in adjusting the temperature of the refrigerant so that the temperature of the refrigerant which is consistently circulated is maintained within a predetermined range.

FIG. 4 is a schematic view illustrating a method for manufacturing a wavelength conversion part according to another embodiment of the disclosed technology. The method for manufacturing a wavelength conversion part of FIG. 4 may be performed using the apparatus for manufacturing a wavelength conversion part described above with reference to FIGS. 1 to 3. Thus, a detailed description of the same configurations as those described in the exemplary embodiments of FIGS. 1 to 3 will be omitted.

### Experimental Example

An experiment for measuring viscosity variation of a resin and a deposition degree of phosphors depending on temperature of the resin was performed. The experiment was performed by comparing a silicon resin including the phosphors maintained at the respective temperatures and the silicon resin left at room temperature to measure viscosity thereof, and results of the experiment are shown in Table 1. A maintaining time was two hours.

TABLE 1

| | Viscosity Variation Rate from |
|---|---|
| Classification | Initial Time to Two Hours |
| Leaving at Room | 38% |
| Temperature | |
| Maintain at 10° C. | −1% |
| Maintain at 20° C. | −1% |
| Maintain at 28° C. | 17% |
| Maintain at 34° C. | 23% |

As shown in the results of Table 1, the case in which the silicon resin is left at the room temperature shows the most outstanding viscosity variation rate of 38%, and the case in which the silicon resin is maintained at a predetermined temperature shows the viscosity variation rate lower than the case in which the silicon resin is left at room temperature. Particularly, it may be seen that the case in which the temperature of the resin is maintained at 10° C. or 20° C. has little viscosity variation.

According to this experiment, a degree of deposition of the phosphors is shown in FIG. 5(a) and FIG. 5(b).

FIG. 5A illustrates the case in which the resin is left at the room temperature, and FIG. 5B illustrates the case in which the temperature of the resin is maintained within a predetermined temperature range. As shown in the photographs, it may be seen that the deposition of the phosphors occurs in the case in which the resin is left at room temperature, and the deposition of the phosphors scarcely occurs in the case in which the temperature of the resin is maintained.

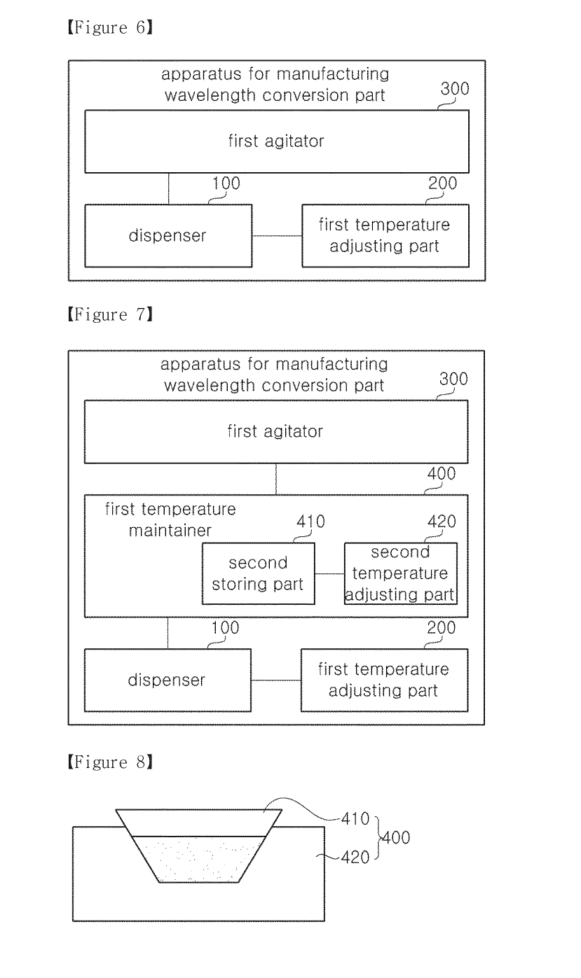

FIG. 6 is a block diagram illustrating a configuration of an apparatus for manufacturing a wavelength conversion part and a method for manufacturing a wavelength conversion part according to another embodiment of the disclosed technology.

Referring to FIG. 6, the apparatus for manufacturing a wavelength conversion part according to the present exemplary embodiment is similar to the apparatus for manufacturing a wavelength conversion part described above with reference to FIGS. 1 to 4, but has a difference in that it further includes a first agitator 300.

The first agitator 300 serves to manufacture a material by combining the resin and the phosphors and agitating the combined resin and phosphors. The resin may include a polymer resin such as an epoxy resin or an acrylic resin, or a silicon resin, as a main material, and may serve as a matrix diffusing the phosphors. In addition, the resin may further include a curing agent. Thus, the resin in which the phosphors are supported may be cured after being supplied to the light emitting apparatus.

The first agitator 300 may include a rotational shaft having a paddle of a screw shape capable of agitating the resin and the phosphors, but is not limited thereto. For example, any agitator may be used as long as it may evenly diffuse the phosphors in the resin.

The phosphors in the resin agitated by the first agitator 300 may have weight in the range of predetermined weight ±0.01 g. As a result, the manufactured light emitting apparatuses may have the same light emission characteristics, for example, the same color coordinate.

The resin agitated by the first agitator 300 may be stored in the first storing part 110 of the dispenser 100, and the temperature of the resin may be adjusted by the first temperature adjusting part 200. A description on adjusting the temperature by the first temperature adjusting part is the same as those described above with reference to FIGS. 1 to 4.

FIG. 7 is a block diagram illustrating an apparatus for manufacturing a wavelength conversion part and a method for manufacturing a wavelength conversion part according to another embodiment of the present invention.

Referring to FIG. 7, the apparatus for manufacturing a wavelength conversion part according to the present exemplary embodiment is similar to the apparatus for manufacturing a wavelength conversion part described above with reference to FIG. 6, but has a difference in that it further includes a first temperature maintainer 400.

The first temperature maintainer 400 serves to maintain the temperature of the resin supplied from the first agitator 300. Thereafter, the resin in the first temperature maintainer 400 is supplied to the dispenser 100. The first temperature maintainer 400 may include a second storing part 410 and a second temperature adjusting part 420.

The second storing part 410 may store the resin supplied from the first agitator 300. Since an agitating apparatus such as the paddle, or the like generates heat in the first agitator 300, the resin needs to be moved to a storing space separated from the first agitator 300, and the second storing part 410 serves as the separate storing space.

The second temperature adjusting part 420 may surround the second storing part 410. Further, the second temperature adjusting part 420 may be connected to the second storing part 410. For example, as illustrated in FIG. 8, the second temperature adjusting part 420 may have a shape surrounding a portion of the second storing part 410. However, the second temperature adjusting part 420 is not limited thereto. For example, the second temperature adjusting part 420 may have a shape surrounding the entire second storing part 410.

The second temperature adjusting part 420 may maintain the temperature of the resin. For example, the second temperature adjusting part 420 may maintain the temperature of the resin in the second storing part 410 within −5° C. to 30° C. As a result, it is possible to prevent the viscosity variation rate of the resin from being different and it is also possible to maintain the resin curing time to be substantially constant. Therefore, the occurrence of the deviation in the light emission characteristics between the light emitting apparatuses which are manufactured in the same process is minimized, thereby making it possible to improve a process yield.

Further, the temperature of the resin in the first agitator 300 is increased during an agitating process. In the case in which the resin having the increased temperature is immediately and consistently injected into the dispenser 100, the resin may be coated on the light emitting apparatus before the temperature of the resin is maintained to be similar to a predetermined temperature by the first temperature adjusting part 200. However, according to the present exemplary embodiment, since the first temperature maintainer 400 maintains the temperature of the resin in advance before the resin is injected into the dispenser 100, the temperature of the coated resin is more uniform, thereby making it possible to further prevent the viscosity variation rate from being differently generated.

Various methods which are known to those skilled in the art may be used for the second temperature adjusting part 420. For example, the second temperature adjusting part 420 may include a thermoelement (not illustrated). Further, the second temperature adjusting part 420 may further include a temperature sensor (not illustrated). The temperature sensor may serve to measure temperature of the second storing part 410, for example, inner temperature of the second storing part 410 to assist in adjusting a degree of absorption and generation of heat of the thermoelement. In this case, a controlling unit (not illustrated) obtaining data from the temperature sensor to adjust an operation of the thermoelement may be further disposed.

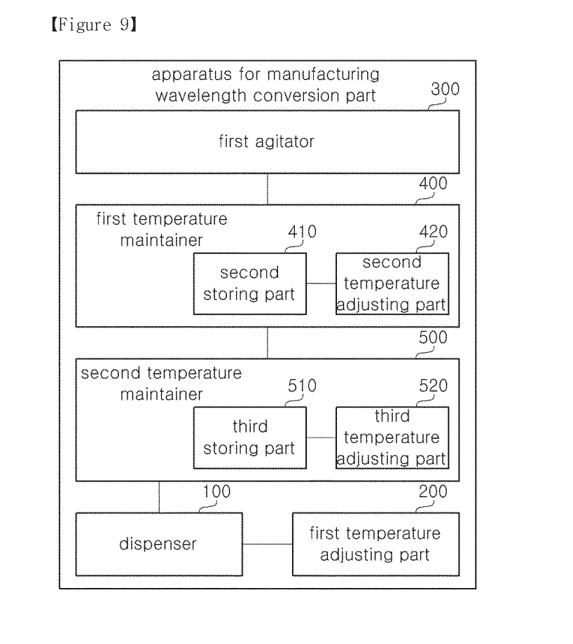

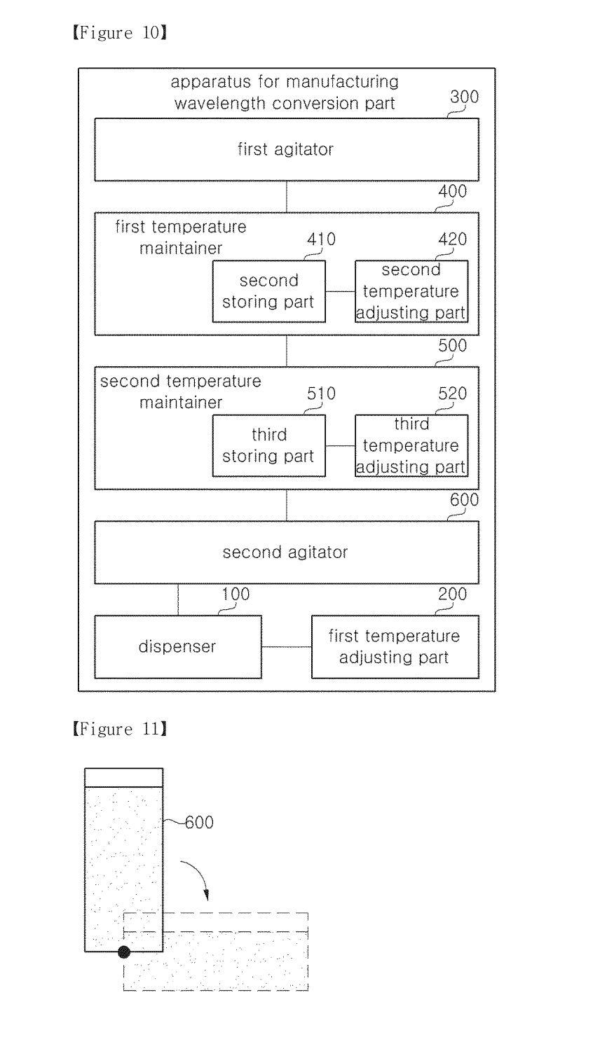

FIG. 9 is a block diagram illustrating an apparatus for manufacturing a wavelength conversion part and a method for manufacturing a wavelength conversion part according to another embodiment of the disclosed technology.

Referring to FIG. 9, the apparatus for manufacturing a wavelength conversion part according to the present exemplary embodiment is similar to the apparatus for manufacturing a wavelength conversion part described above with reference to FIG. 7, but has a difference in that it further includes a second temperature maintainer 500.

The second temperature maintainer 500 serves to store the resin supplied from the first temperature maintainer 400 and maintain the temperature of the resin. Thereafter, the resin in the second temperature maintainer 500 is supplied to the dispenser 100. Further, the second temperature maintainer 500 may receive more resin than the resin which may be received in the second storing part 410 of the first temperature maintainer 400, in order to mass-produce the light emitting apparatus.

The second temperature maintainer 500 may include at least one third storing part 510 and a third temperature adjusting part 520.

The third storing part 510 may store the resin supplied from the first temperature maintainer 400. The third storing part 510 may have a cylindrical shape in which an inner portion of the third storing part 510 is empty, but is not necessarily limited thereto. The third storing part 510 may have capacity greater than that of the second storing part 410. For example, inner capacity of the third storing part 510 may be 500 g. When the above-mentioned capacity is satisfied, the light emitting apparatus may be sufficiently mass-produced only by the resin stored once in the third storing part 510.

The third storing part 510 may include a separate apparatus capable of agitating the resin in the third storing part 510. For example, the third storing part 510 may be designed to be rotated on a vertical shaft in a vertical direction. Thereby, the deposition of the phosphors in the resin is prevented, thereby making it possible to minimize deviation in a phosphor distribution in the resin.

The third temperature adjusting part 520 may be connected to the third storing part 510. The third temperature adjusting part 520 may have a shape surrounding a portion of the third storing part 510. However, the shape of the third temperature adjusting part 520 is not limited thereto. For example, the third temperature adjusting part 520 may have a shape surrounding the entire third storing part 510.

The third temperature adjusting part 520 may maintain the temperature of the resin. Specifically, the third temperature adjusting part 520 may maintain the temperature of the resin in the third storing part 510 within −5° C. to 30° C. As a result, the viscosity variation rate of the resin may be maintained, and deviation in light emission characteristics of the manufactured light emitting apparatuses may be minimized. In addition, the third temperature adjusting part 520 may maintain the temperature of the resin for long time. For example, the third temperature adjusting part 520 may maintain the temperature of the resin for 36 hours or less. The light emitting apparatus may be supplied to a process of manufacturing a wavelength conversion part for a specific time, and may be, for example, supplied for 36 hours at maximum. As a result, in the above-mentioned configuration, since the temperature of the resin may be maintained according to the time in which the light emitting apparatus is supplied, the viscosity variation rate of the resin may be maintained, and deviation in light emission characteristics of the manufactured light emitting apparatuses may be minimized.

The third temperature adjusting part 520 may adjust temperature deviation of a plurality of third storing parts 510. For example, the third temperature adjusting part 520 may be connected to the plurality of third storing parts 510 to measure and compare inner temperatures of the respective third storing parts 510, and may independently adjust the inner temperatures of the respective third storing parts 510 so that the inner temperature has a deviation value less than a predetermined deviation value. However, the independent adjustment has been provided as one example and the third temperature adjusting part 520 is not limited thereto. For example, the third temperature adjusting part 520 may adjust the inner temperatures of the third storing parts 510 at once.

Various methods which are known to those skilled in the art may be used for the third temperature adjusting part 520. For example, the third temperature adjusting part 520 may include a thermoelement (not illustrated). Further, the third temperature adjusting part 520 may further include a temperature sensor (not illustrated). The temperature sensor may serve to measure the temperature of the third storing part 510, for example, the inner temperature of the third storing part 510 to assist in adjusting a degree of absorption and generation of heat of the thermoelement. In this case, a controlling unit (not illustrated) obtaining data from the temperature sensor to adjust an operation of the thermoelement may be further disposed. The respective third storing parts 510 may be connected to the temperature sensor and the thermoelement one to one. As a result, it is possible to independently adjust each of the inner temperatures of the plurality of third storing parts 510 by the controlling unit of the third temperature adjusting part 520.

In some implementations, the controlling unit of the third temperature adjusting part 520 does not independently adjust each of the inner temperatures of the plurality of third storing parts 510, but may adjust the inner temperatures of the plurality of third storing parts 510 at once. In this case, the thermoelements connected to each of the third storing parts 510 may be incorporated into one so as to be adjusted by the controlling unit. In addition, the temperature sensor (not illustrated) may be disposed to measure temperature of the incorporated thermoelement. In this case, the third storing part 510 and the temperature sensor need not to be in contact with each other, and a problem that the temperature sensor is damaged by a frequent opening and closing of the third storing part 510 may also be minimized.

FIG. 10 is a block diagram illustrating a configuration of an apparatus for manufacturing a wavelength conversion part and a method for manufacturing a wavelength conversion part according to another embodiment of the present invention.

Referring to FIG. 10, the apparatus for manufacturing a wavelength conversion part according to the present exemplary embodiment is similar to the apparatus for manufacturing a wavelength conversion part described above with reference to FIG. 9, but has a difference in that it further includes a second agitator 600.

The second agitator 600 may store the resin supplied from the second temperature maintainer 500. In addition, the second agitator 600 may serve to again diffuse the phosphors deposited in the resin. Thereafter, the resin in the second agitator 600 is supplied to the dispenser 100.

The second agitator 600 may be connected to the third storing part 510 of the second temperature maintainer 500. If there are the plurality of third storing parts 510, the resins of the plurality of third storing parts 510 may be collected by the second agitator 600 and the collected resin may be stored in the second agitator 600. The second agitator 600 may have a cylindrical shape, but is not limited thereto.

The second agitator 600 may be inclined at a predetermined gradient and may be then returned again to an original state. One-time operation of the second agitator 600 described above may refer to 1 cycle. As a phase of the resin is moved in the second agitator 600 during 1 cycle, the phosphors in the resin are also moved. For example, the phosphors are in a state in which they are more distributed in a lower portion of the resin than an upper portion of resin by gravity, and as the second agitator 600 is inclined during 1 cycle, the phosphors concentrated on the lower portion of the resin may be moved to other regions of the resin. Thereby, the deposition of the phosphors in the resin is prevented, thereby making it possible to minimize deviation in a phosphor distribution in the resin.

The second agitator 600 may be inclined at an angle of 90° to −90° from a vertical direction during 1 cycle and may be then returned again to the vertical direction. For example, as illustrated in FIG. 11, the second agitator 600 may be inclined at an angle of 90° to −90° on the basis of one axis across a center of a lower surface of the second agitator 600 and may be then returned again to the vertical direction. In the case in which the second agitator 600 is inclined at an angle which is less than 10°, since the resin in the second agitator 600 is not sufficiently moved, the diffusion of the phosphors in the resin is not smoothly performed. As a result, the deviation in the light emission characteristics of the manufactured light emitting apparatuses is not reduced. In the case in which the second agitator 600 is inclined at an angle exceeding 90°, bubbles occur by excessive cycle speed and an excessive phase change of the resin, which causes degradation of reliability of the light emitting apparatus.

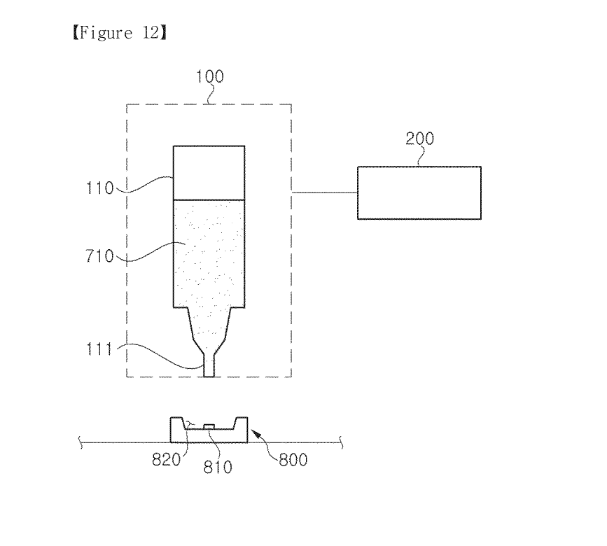

FIG. 12 is a schematic view illustrating a method for manufacturing a wavelength conversion part according to another embodiment of the disclosed technology.

Referring to FIG. 12, the method for manufacturing a wavelength conversion part includes an operation of preparing a dispenser 100 in which a resin 710 having phosphors uniformly mixed and supported therein is filled, and an operation of coating the resin from a dispenser 100 to a light emitting apparatus 800.

The resin 710 in which the phosphors are supported may include a polymer resin such as an epoxy resin or an acrylic resin, or a silicon resin, and may further include a curing agent, a curing inhibitor, or a catalyst. The phosphors may excite incident light and may convert the excited incident light into light having different wavelength. The phosphors may include various phosphors which are widely known to those skilled in the art. For example, the phosphors may include at least one of garnet type phosphor, aluminate phosphor, sulfide phosphor, oxynitride phosphor, nitride phosphor, fluoride based phosphor, or silicate phosphor. However, the disclosed technology is not limited thereto.

The phosphors may be mixed in the resin 710 to have generally uniform concentration, and the resin 710 in which the phosphors are supported may be prepared by mixing the phosphors and the resin using an electric mixer, or the like.

In the operation of coating the resin 710 from the dispenser 100 to the light emitting apparatus 800, the dispenser 100 may be maintained at substantially constant temperature by the first temperature adjusting part 200. The temperature of the dispenser 100 is adjusted, thereby making it possible to also maintain temperature of the resin 710 in the dispenser 100 at substantially constant temperature. For example, the temperature of the resin 710 may be maintained at a predetermined temperature within a range of ±3° C., and may also be maintained at a predetermined temperature within a range of temperature of ±5° C. Further, the temperature of the resin 710 may be maintained at a constant temperature. In some implementations, the predetermined temperature may be in −5° C. to 30° C. In some implementations, the predetermined temperature may be in −5° C. to 25° C. In some implementations, the predetermined temperature may be in −5° C. to 20° C.

The temperature of the resin 710 in the dispenser 100 may be maintained to be substantially constant, such that a viscosity variation rate of the resin 710 may be maintained to be constant, thereby making it possible to allow a curing time of the resin to be constant at a predictable level. In addition, the viscosity variation rate is maintained to be constant, thereby making it possible to retard the phosphors in the resin 710 to be deposited. Therefore, it is possible to prevent an occurrence of deviation in light emission characteristics of the light emitting apparatus 800 according to a manufacturing timing of the wavelength conversion part.

Meanwhile, the light emitting apparatus 800 may be or include a light emitting diode package, as illustrated. The light emitting diode package may include a light emitting diode 810, and may also have a cavity 820 in which the light emitting diode 810 is disposed. The resin 710 supplied from the apparatus for manufacturing a wavelength conversion part may be filled in the cavity 820, thereby covering the light emitting diode 810 to be disposed on a light emitting path.

The light emitting apparatus 800 has been provided as an example, and the method for manufacturing a wavelength conversion part according to the disclosed technology may be used for various light emitting apparatuses 800.

Referring to FIG. 6, a method for manufacturing a wavelength conversion part according to another exemplary embodiment of the disclosed technology may include an operation of forming a resin in which phosphors are uniformly mixed and supported by combining and agitating the phosphors and the resin by the first agitator 300. The resin in which the phosphors are supported may be supplied to the dispenser 100 from the first agitator 300. The phosphors in the resin agitated by the first agitator 300 may have weight in the range of predetermined weight ±0.01 g. As a result, the manufactured light emitting apparatuses may have the same light emission characteristics, for example, the same color coordinate.

Referring to FIG. 7, a method for manufacturing a wavelength conversion part according to another exemplary embodiment of the disclosed technology is similar to the method for manufacturing a wavelength conversion part described above with reference to FIG. 6, but has a difference in that it may further include an operation of maintaining temperature of the resin supplied to the first agitator 300 through the first temperature maintainer 400. The first temperature maintainer 400 may include the second storing part 410 storing the resin and the second temperature adjusting part 420 connected to the second storing part 410. The second temperature adjusting part 420 may maintain the temperature of the resin in the second storing part 410 within −5° C. to 30° C. As a result, it is possible to prevent the viscosity variation rate of the resin from being differently generated and it is also possible to maintain the resin curing time to be substantially constant. Therefore, the occurrence of the deviation in the light emission characteristics between the light emitting apparatuses which are manufactured in the same process is minimized, thereby making it possible to improve a process yield.

Referring to FIG. 9, a method for manufacturing a wavelength conversion part according to another exemplary embodiment of the disclosed technology is similar to the method for manufacturing a wavelength conversion part described above with reference to FIG. 7, but has a difference in that it may further include an operation of storing the resin supplied to the first temperature maintainer 400 through the second temperature maintainer 500 and maintaining the temperature of the resin. The second temperature maintainer 500 may include the third storing part 510 storing the resin and the third temperature adjusting part 520 connected to the third storing part 510. The third temperature adjusting part 520 may maintain the temperature of the resin in the third storing part 510 within −5° C. to 30° C. The resin in the third storing part 510 may be agitated through the second temperature maintainer 500. As a result, it is possible to prevent the viscosity variation rate of the resin from being differently generated and it is also possible to maintain the resin curing time to be substantially constant. Therefore, the occurrence of the deviation in the light emission characteristics between the light emitting apparatuses which are manufactured in the same process is minimized, thereby making it possible to improve a process yield.

Referring to FIG. 10, a method for manufacturing a wavelength conversion part according to another exemplary embodiment of the disclosed technology is similar to the method for manufacturing a wavelength conversion part described above with reference to FIG. 9, but has a difference in that it may further include an operation of agitating the resin supplied from the second temperature maintainer 500 by the second agitator 600. The second agitator 600 may be inclined at an angle of 90° to −90° from a vertical direction and may be then returned again to the vertical direction. Thereby, the deposition of the phosphors in the resin is physically prevented, thereby making it possible to minimize deviation in a phosphor distribution in the resin.

According to the exemplary embodiments of the disclosed technology, the apparatus for manufacturing the wavelength conversion part capable of uniformly maintaining the temperature of the resin at the time of manufacturing the wavelength conversion part and the method for manufacturing the wavelength conversion part using the same are provided, thereby making it possible to minimize the occurrence of the deviation in the light emission characteristics of the plurality of light emitting apparatuses which are manufactured. Thus, a yield of a process of manufacturing the light emitting apparatus may be improved. In addition, by a large temperature maintainer, it is possible to mass-produce the plurality of light emitting apparatuses and it is possible to minimize the occurrence of the deviation in the light emission characteristics of the plurality of light emitting apparatuses which are mass-produced.

Hereinabove, various exemplary embodiments and experimental examples has been described. The disclosed technology is not limited thereto and may be further modified and altered in various manners.

What is claimed is:

1. An apparatus for manufacturing a wavelength conversion part of a light emitting apparatus, the apparatus for manufacturing the wavelength conversion part comprising:
a dispenser including a first storing part configured to store materials including a resin and phosphors; and
a first temperature adjusting part connected to the dispenser,
wherein the first temperature adjusting part includes a temperature sensor.

2. The apparatus for manufacturing a wavelength conversion part of claim 1, wherein the first temperature adjusting part includes a water cooler, and
the water cooler includes:
a circulation pipe at least partially surrounding the dispenser and providing a passage for water to flow, and
a temperature adjusting apparatus connected to the circulation pipe to maintain a temperature of the water to be constant.

3. The apparatus for manufacturing a wavelength conversion part of claim 1, wherein the first temperature adjusting part includes:
a body;
a thermoelement disposed in the body;
an air circulation part disposed apart from the body and surrounding the dispenser;
a first air passage connected to the body and introducing air into the body;
a second air passage connected to the body and moving the air between the body and the air circulation part; and
a third air passage connected to the air circulation part and discharging the air from the air circulation part to the outside.

4. The apparatus for manufacturing a wavelength conversion part of claim 3, wherein
the body includes an air pump and provides an air circulation path circulating the air inside of the body, and
the thermoelement adjusts the temperature of the air in the air circulation path to maintain a constant temperature.

5. The apparatus for manufacturing a wavelength conversion part of claim 1, wherein the first temperature adjusting part further includes:
a thermoelement; and
a clamp in contact with the dispenser.

6. The apparatus for manufacturing a wavelength conversion part of claim 5, wherein the temperature sensor is in contact with the dispenser or the clamp.

7. The apparatus for manufacturing a wavelength conversion part of claim 1, wherein the first temperature adjusting part includes an air compression cooler, and
the air compression cooler includes:
a compressor including refrigerant gas and compressing the refrigerant gas to provide a heated refrigerant gas;
a cooler receiving the heated refrigerant gas from the compressor and cooling the received refrigerant gas to provide a liquefied refrigerant;
an expanding valve receiving the liquefied refrigerant from the cooler and cooling the received liquefied refrigerant to provide the refrigerant gas; and
a circulation pipe configured to at least partially surround the dispenser and providing a passage inside of the circulation pipe for the refrigerant gas provided from the expanding valve.

8. The apparatus for manufacturing a wavelength conversion part of claim 1, wherein the first temperature adjusting part maintains a temperature of the resin in the dispenser within a range of ±5° C. of a predetermined temperature.

9. The apparatus for manufacturing a wavelength conversion part of claim 8, wherein the predetermined temperature is in a range of −5° C. to 30° C.

10. The apparatus for manufacturing a wavelength conversion part of claim 1, further comprising a first agitator mixing the phosphors in the resin.

11. The apparatus for manufacturing a wavelength conversion part of claim 10, further comprising a first temperature maintainer maintaining a temperature of the resin supplied from the first agitator.

12. The apparatus for manufacturing a wavelength conversion part of claim 11, wherein the first temperature maintainer includes:
a second storing part storing the resin; and
a second temperature adjusting part surrounding the second storing part, and
the second temperature adjusting part maintains a temperature of the resin in the second storing part within −5° C. to 30° C.

13. The apparatus for manufacturing a wavelength conversion part of claim 11, further comprising a second temperature maintainer storing the resin supplied from the first temperature maintainer and maintaining a temperature of the resin.

14. The apparatus for manufacturing a wavelength conversion part of claim 13, wherein the second temperature maintainer includes:
at least one of third storing part storing the resin; and
a third temperature adjusting part connected to the third storing part, and
the third temperature adjusting part maintains temperature of the resin in the third storing part within −5° C. to 30° C.

15. A method for manufacturing a wavelength conversion part comprising:
preparing a dispenser configured to hold a resin and phosphors;
coating the resin to a light emitting apparatus from the dispenser;
maintaining a temperature of the resin in the dispenser; and
sensing a temperature of the heat exchange medium.

16. The method for manufacturing a wavelength conversion part of claim 15, wherein the temperature of the resin in the dispenser is maintained within a range of ±5° C. of a predetermined temperature.

17. The method for manufacturing a wavelength conversion part of claim 16, wherein in the coating of the resin to the light emitting apparatus, the predetermined temperature is in a range of −5° C. to 30° C.

18. The method for manufacturing a wavelength conversion part of claim 17, wherein the preparing of the dispenser includes mixing the resin with the phosphors.

19. The method for manufacturing a wavelength conversion part of claim 18, further comprising:
storing the mixed resin with the phosphors; and
maintaining a temperature of the stored mixed resin within a range of 5° C. to 30° C.

20. The method for manufacturing a wavelength conversion part of claim 19, further comprising additionally performing a mixing process for the stored mixed resin.
